(19) United States
(12) Patent Application Publication
(10) Pub. No.: US 2005/0121175 A1
(43) Pub. Date: Jun. 9, 2005

(54) Structurally sealed heat sink

(75) Inventor: Yaw-Huey Lai, Taipei Hsien (TW)

Correspondence Address: BACON & THOMAS, PLLC, 625 SLATERS LANE, FOURTH FLOOR, ALEXANDRIA, VA, 22314, US

(73) Assignee: TAI-SOL ELECTRONICS CO., LTD., TAIPEI HSIEN (TW)

(21) Appl. No.: 10/773,151

(22) Filed: Feb. 9, 2004

(30) Foreign Application Priority Data
Dec. 5, 2003 (TW) 92221481

(51) Int. Cl. H05K 7/20

(52) U.S. Cl. 165/104.33

(57) ABSTRACT

A structurally sealed heat sink is composed of a main body, at least one sealing member, and at least one solder unit. The main body includes a chamber inside, a capillary layer adhered to a peripheral surface of said chamber, and at least one opening having a predetermined depth to define a peripheral wall of a predetermined height. The sealing member that is identical to the opening in number includes an intersection intersected with the opening for the predetermined depth, a solder ditch formed between the sealing member and the main body, and an annular groove formed between the peripheral wall and an outer periphery of the sealing member. The solder unit that is identical to the opening in number is disposed inside the solder ditch.

### BACKGROUND OF THE INVENTION

1. Field of the Invention

The present invention relates generally to heat-dissipating apparatuses, and more particularly to a structurally sealed heat sink that is securely sealed to keep solder from leaking inside and ruining a capillary wick while soldering.

2. Description of the Related Art

A conventional heat sink is generally composed of a top shell member and a bottom shell member mounted with each other, a chamber being formed between the top and bottom shell members, and a capillary wick mounted inside the chamber. As shown in FIG. 11, the aforementioned heat sink 90 has an opening 94 sealed by inserting a heat pipe 91 into the opening 94 and placing solder 96 around the opening 94 and then melting the solder 96, as shown in FIG. 12, the solder 96 being melted to flow to a gap formed between the heat pipe 91 and the opening 94 and is then solidified.

However, the aforementioned melted solder 96 before solidification will flow into the gap between the opening 94 and the heat pipe 91 and parts of the solder 96 may be absorbed into the chamber to further sink into the capillary wick to further ruin the capillary wick, such that the capillary wick will malfunction. In addition, while parts of the solder 96 are absorbed into the chamber, the solder 96 around the soldering point will be sufficient to securely seal the gap to further incur defective heat sink.

Another conventional heat sink 100, as shown in FIG. 13, includes a metallic block 101 having an opening 102 formed at its lateral side, a sealing member 103 mounted to the opening 102, and solder 105 disposed between the sealing member 103 and the opening 102. When the solder 105 is melted, parts of the solder 105 may sink into the metallic block 101 to case the same problem. Therefore, an improvement to prevent the solder from sinking inside is required.

### SUMMARY OF THE INVENTION

The primary objective of the present invention is to provide a structurally sealed heat sink that prevents melted solder from sinking into a chamber to be effectively sealed and further prevents a capillary wick inside the chamber from malfunction caused by that the melted solder sinks into to ruin the capillary wick.

The foregoing objective of the present invention is attained by the structurally sealed heat sink that is composed of a main body, at least one sealing member, and at least one solder unit. The main body includes a chamber inside, a capillary layer adhered to a peripheral surface of said chamber, and at least one opening having a predetermined depth to define a peripheral wall of a predetermined height. The sealing member that is identical to the opening in number includes an intersection intersected with the opening for the predetermined depth, a solder ditch formed between the sealing member and the main body, and an annular groove formed between the peripheral wall and an outer periphery of the sealing member. The solder unit that is identical to the opening in number is disposed inside the solder ditch.

### BRIEF DESCRIPTION OF THE DRAWINGS

FIG. 1 is a sectional view of a first preferred embodiment of the present invention after a soldering process;

FIG. 2 is a partially enlarged view of FIG. 1;

FIG. 3 similar to FIG. 2 shows the present invention before the soldering process;

FIG. 4 is a sectional view of a second preferred embodiment of the present invention before the soldering process;

FIG. 5 similar to FIG. 4 shows the present invention after the soldering process;

FIG. 6 is a sectional view of a third preferred embodiment of the present invention before the soldering process;

FIG. 7A is a partially enlarged view of FIG. 6, showing the present invention before the soldering process;

FIG. 7B is a partially enlarged view of FIG. 6, showing the present invention after the soldering process;

FIG. 8 is a sectional view of a fourth preferred embodiment of the present invention before the soldering process;

FIG. 9 similar to FIG. 8 shows the present invention after the soldering process;

FIG. 10 is a sectional view of a fifth preferred embodiment of the present invention after the soldering process;

FIG. 11 is a sectional view of the prior art before the soldering process;

FIG. 12 is a sectional view of the prior art after the soldering process; and

FIG. 13 is a sectional view of another prior art after the soldering process.

### DETAILED DESCRIPTION OF THE INVENTION

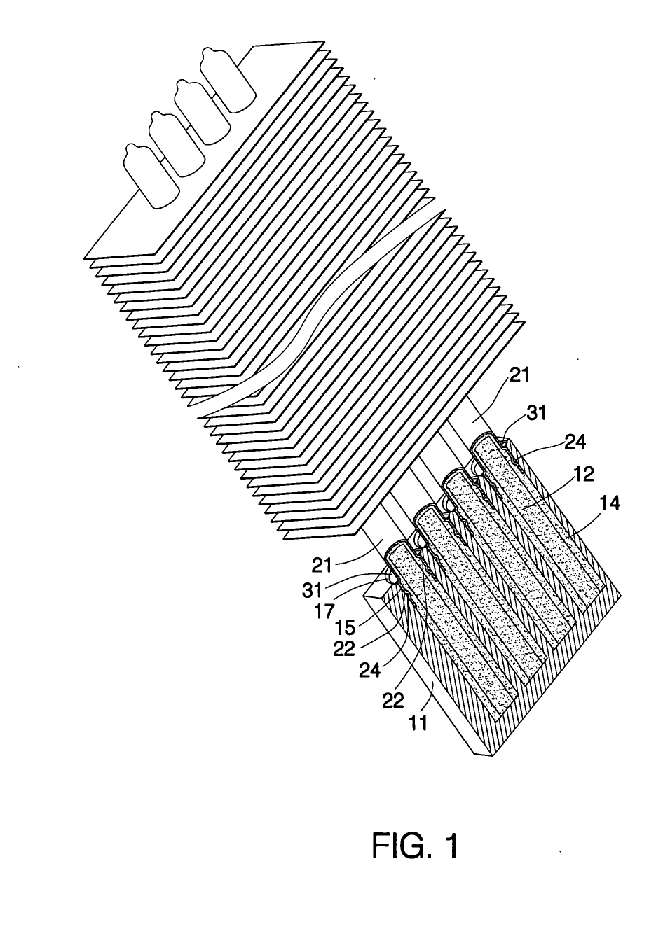

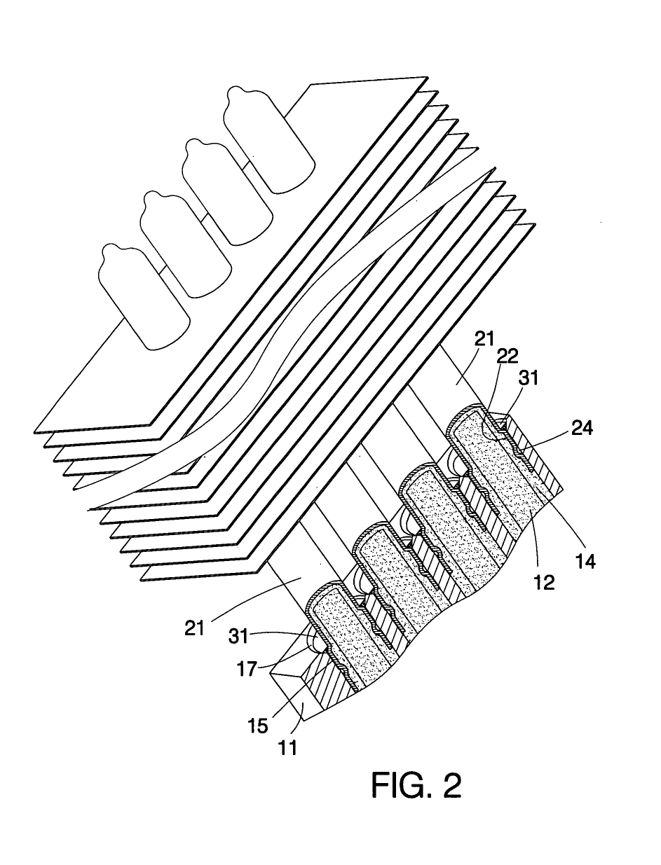

Referring to FIGS. 1-2, a structurally sealed heat sink 10 constructed according to a first preferred embodiment of the present invention is composed of a main body 11, a plurality of sealing member 21, and a plurality of solder units 31.

The main body 11 is embodied as a metallic block, including a plurality of tunnels extending from a lateral side thereof towards inside to define a plurality of chambers 12, a plurality of capillary layers 14 respectively disposed around peripheral surfaces of the chambers 12, a plurality of openings 15 having predetermined depth, and a plurality of solder ditches 17 respectively formed at free ends of the openings 15.

The sealing members 21 are the same with the openings 15 in number and are embodied as heat pipes, each of which includes an intersection 22 of a predetermined length at a free end thereof for plugging into the opening 15 for the predetermined depth, a predetermined length located outside the main body 11, and an annular groove 24 recessed around an outer periphery of the intersection 22.

The solder units 31 are the same with the openings 15 in number, respectively disposed in the solder ditches 17.

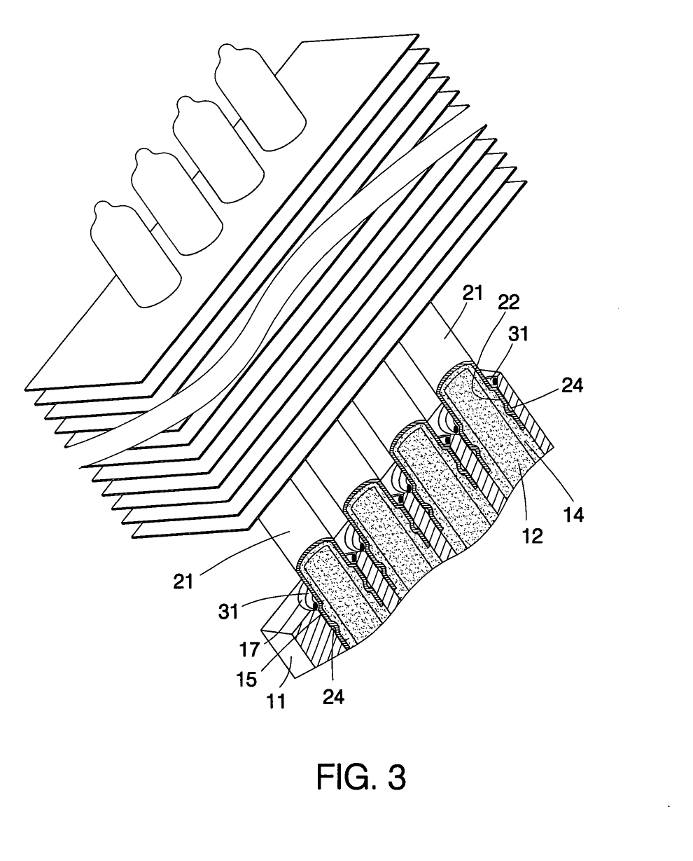

Referring to FIGS. 2 and 3, the present invention improves the prior art by that the solder units 31 will not be absorbed into the chambers 12 by capillary action and not further vitiate the capillary layers 14, thereby causing better sealing effect than the prior art. Each of the solder units 31 is melted and is then driven by the capillary action to flow into a gap formed between each sealing member 21 and each opening 15 to ultimately converge in each annular groove 24 not to further entering each chamber 12. Therefore, the solder units 31 not only remain in predetermined positions to seal the gaps, but also keep from entering the chambers and further vitiating the capillary layers 14.

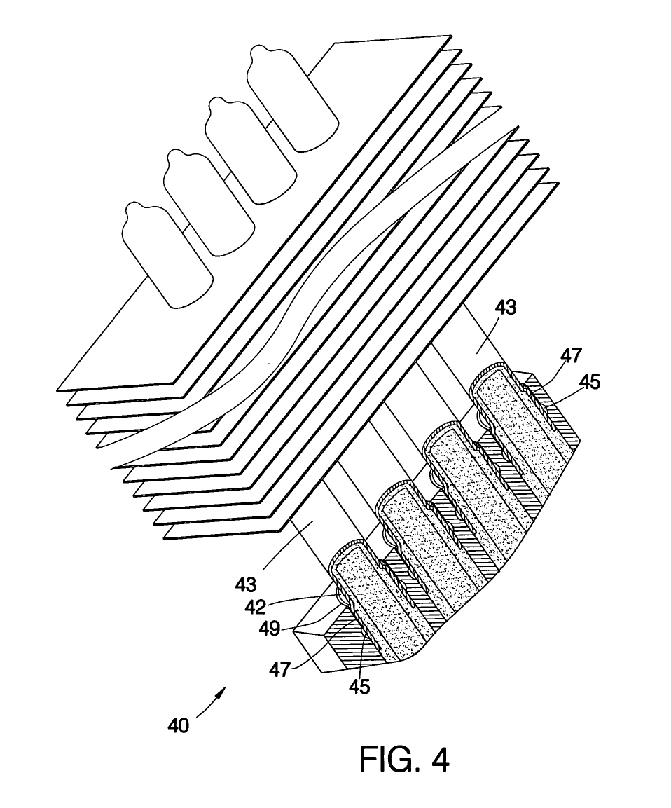

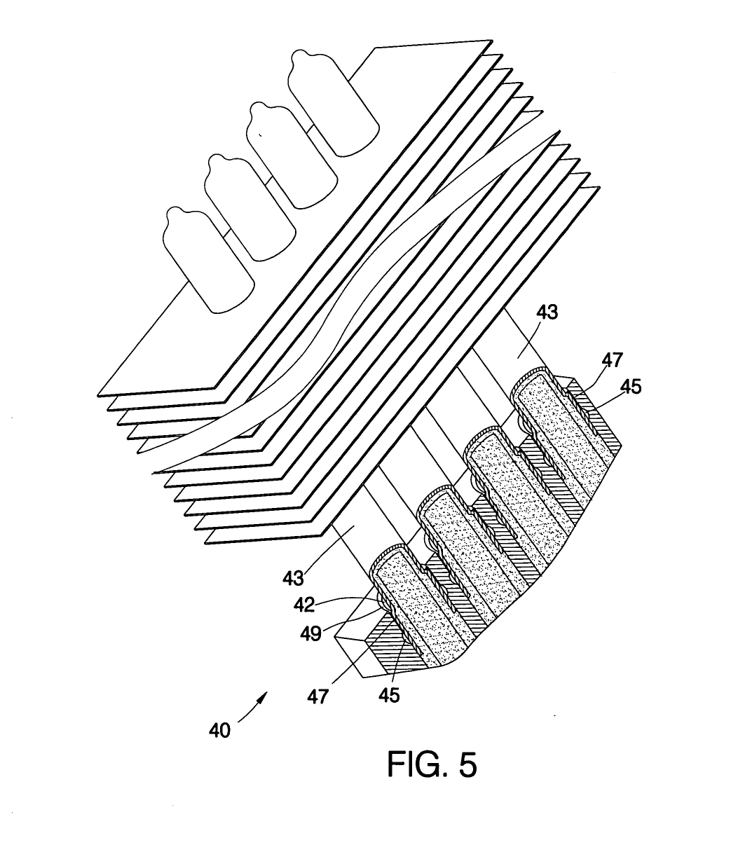

Referring to FIGS. 4 and 5, the heat sink 40 constructed according to a second preferred embodiment of the present invention is different from the first preferred embodiment by that each of the solder ditches 42 is recessed around an outer periphery of the sealing member 43 for receiving the solder unit 49, and each of the annular grooves 41 is recessed around the opening 47 of the main body 41 for preventing the solder units 49 from entering the chambers and further vitiating the capillary layers.

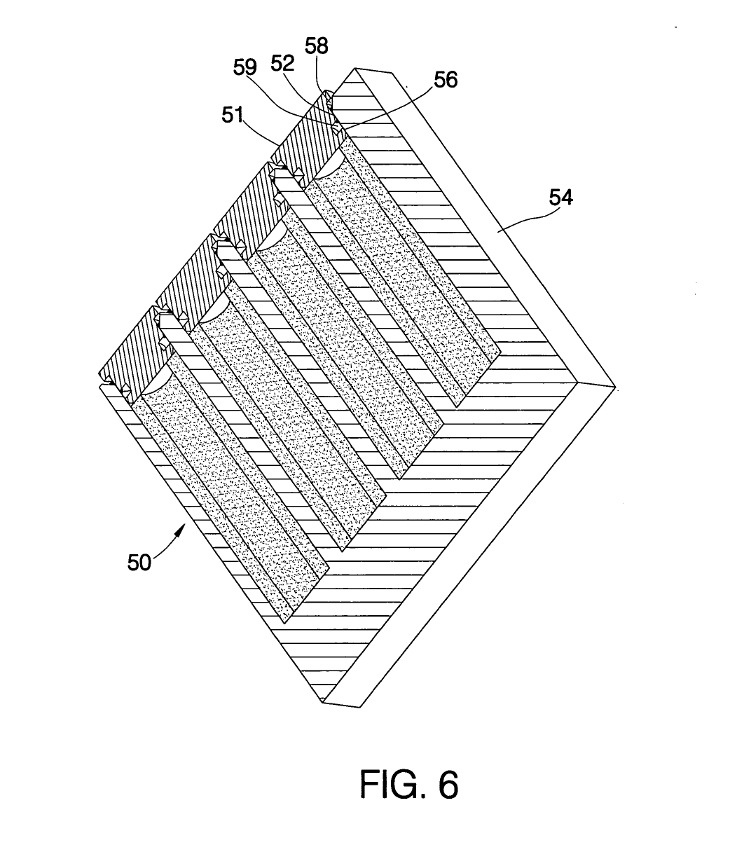

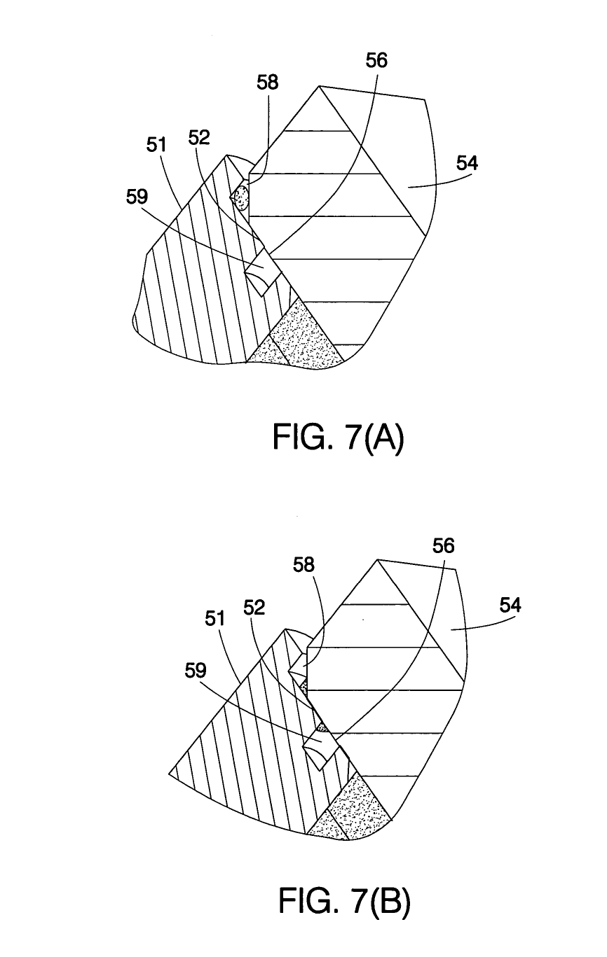

Referring to FIGS. 6, 7A, and 7B, the heat sink 50 constructed according to a third preferred embodiment of the present invention is different from the aforementioned preferred embodiment by that each of the sealing members 51 is a stopping member and includes an intersection 52 plugged into each of the openings 56 for the predetermined depth, each of the solder ditches 58 is formed at a free end of the opening 56, and each of the annular grooves 59 is formed at a peripheral edge of the intersection 52.

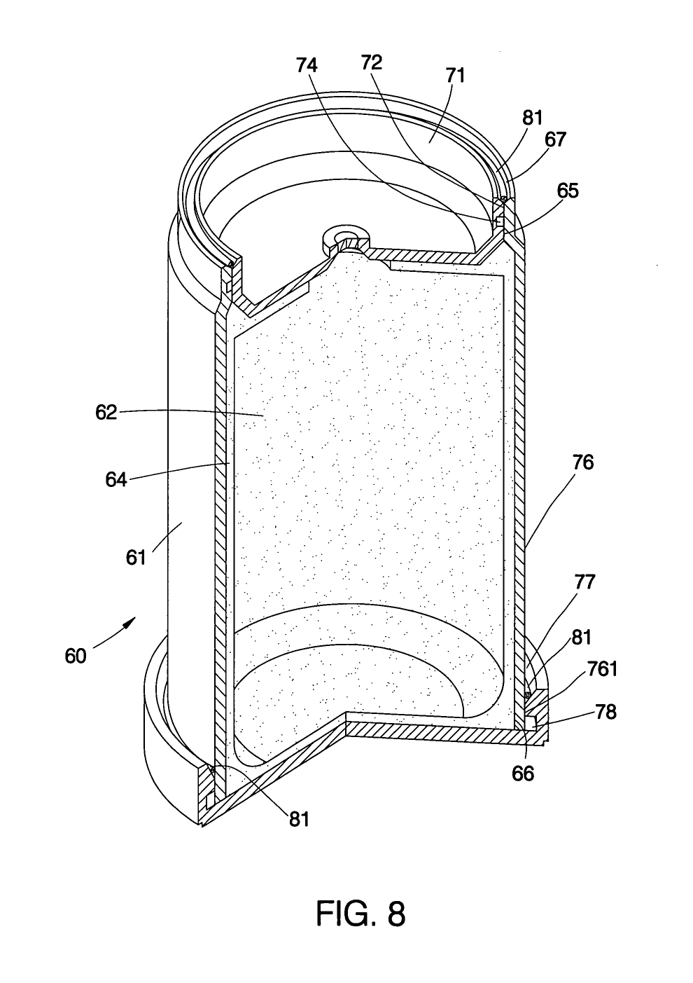

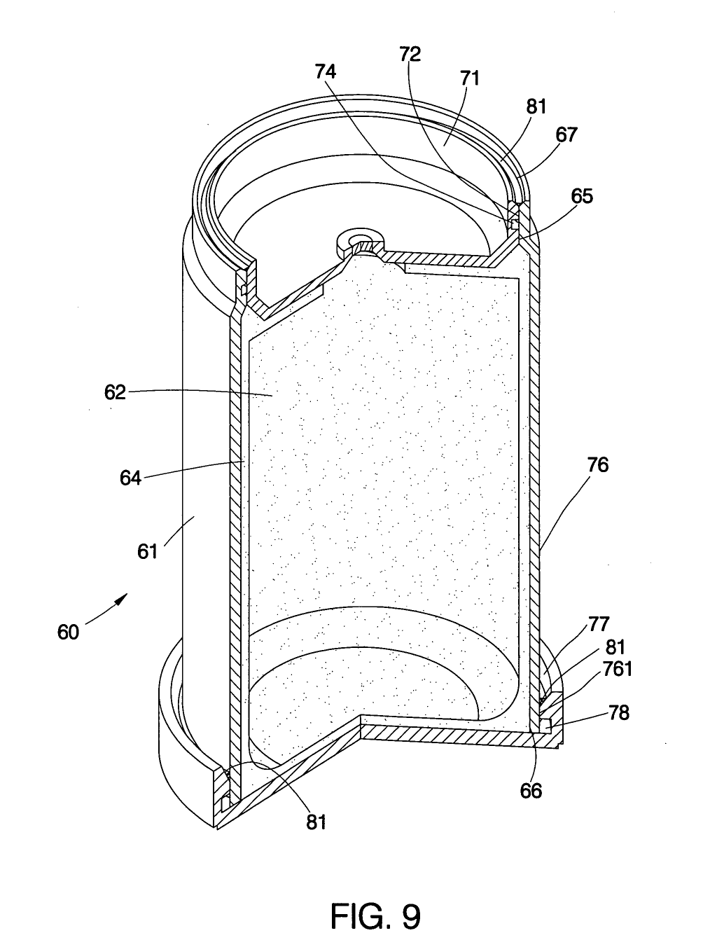

Referring to FIGS. 8 and 9, the heat sink 60 constructed according to a fourth preferred embodiment of the present invention is composed of a main body 61, two sealing members (a first sealing member 71 and a second sealing member 76), and a plurality of solder units 81.

The main body 61 is embodied as a heat pipe, including a chamber 62 inside, a capillary layer 64 disposed at a peripheral surface of the chamber 62, two openings (a first opening 65 and a second opening 66) extending for a predetermined depth, and a solder ditch 67 is formed around a free end of the opening 65.

The first sealing member 71 is a stopping barrel member, including an intersection 72 plugged into the first opening 65 for the predetermined depth and an annular groove 74 recessed around an outer periphery of the intersection 72. The second sealing member 76 is a sleeve, including an intersection 761 fitted into the second opening 66, a solder ditch 77 recessed around an end thereof, and an annular groove 78 recessed around an inner periphery thereof.

The solder units 81 are the same with the openings 65 and 66 in number and are respectively disposed in the solder ditches 67 and 77.

The two annular grooves 74 and 78 can prevent the melted solder units from entering the chamber 62 by the capillary action. In addition, the annular grooves 74 and 78 can alternatively be formed on the main body 61 to have the aforementioned function.

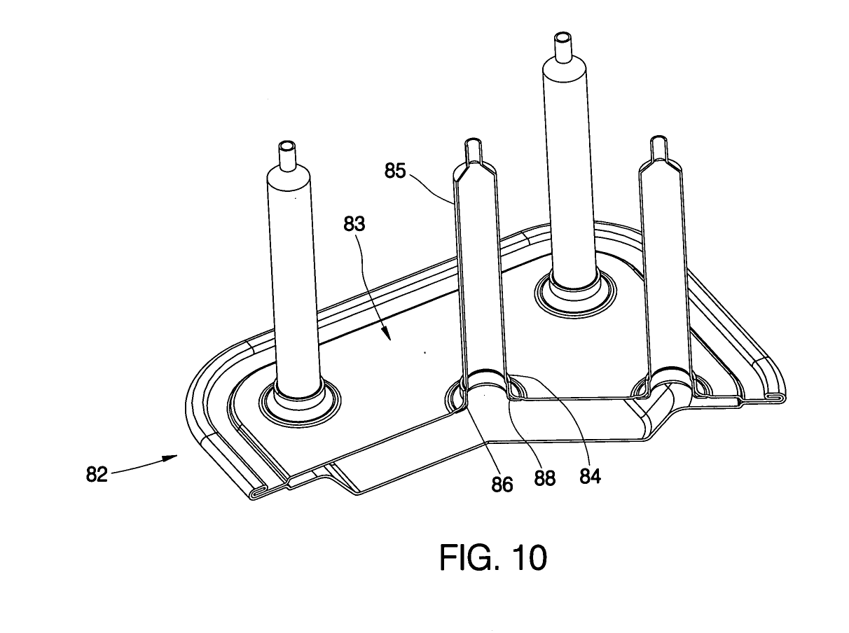

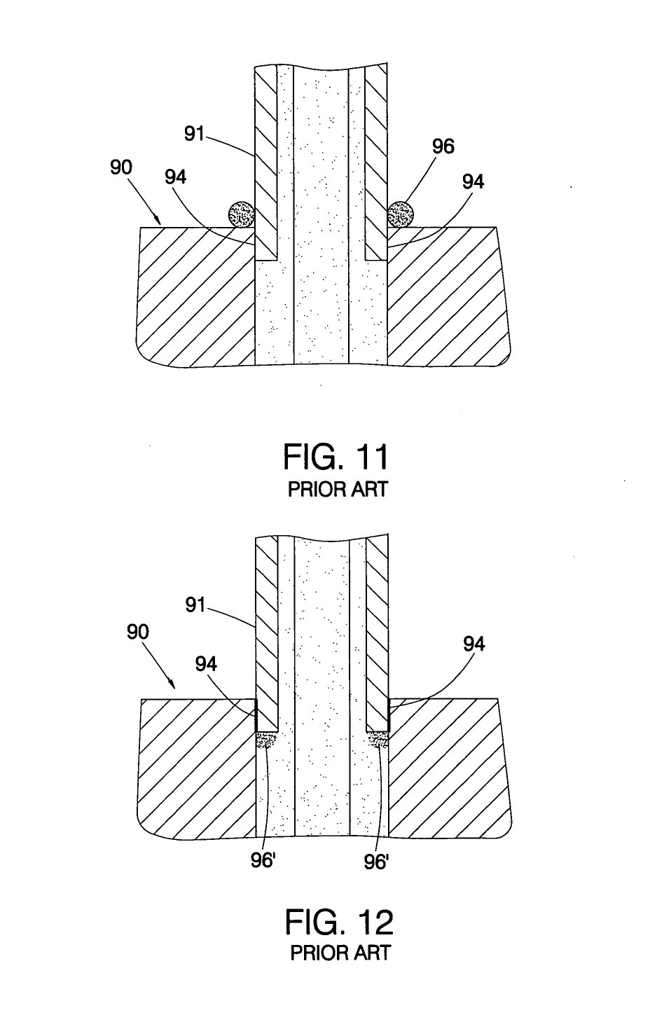

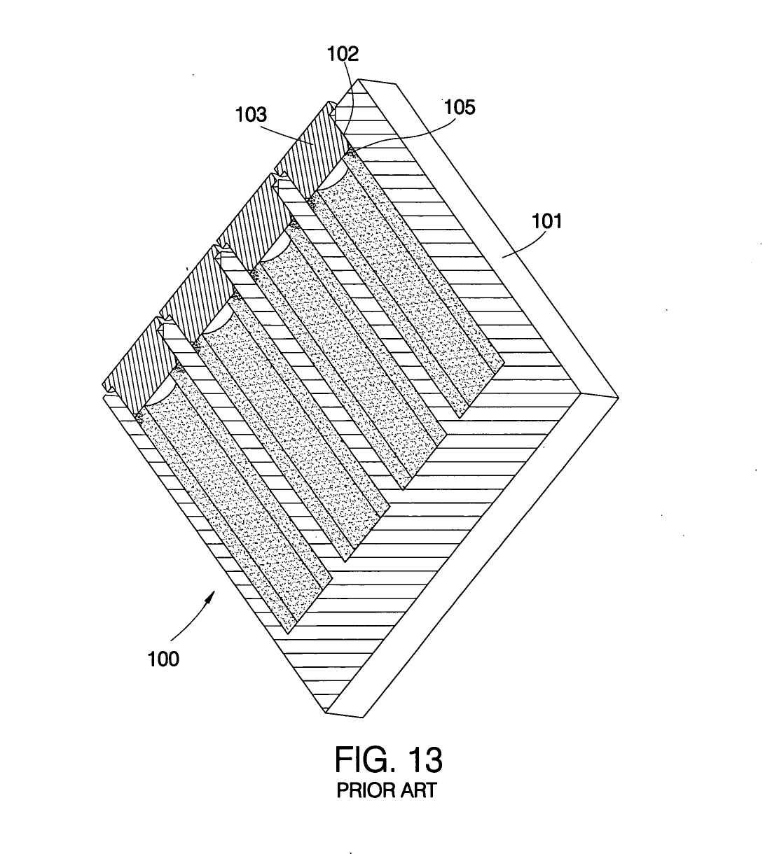

Referring to FIG. 10, the heat sink 82 constructed according to a fifth preferred embodiment of the present invention is different from the first preferred embodiment by that a peripheral wall around each of the openings 84 of the main body 83 extends upwards from the main body 83 for a predetermined length, and the intersection 86 of each of the sealing members 85 is plugged into the opening 84 and extends downwards and then outwards along a diametric direction of the opening 84. The intersection 86 is larger than the peripheral wall in curvature, such that an annular groove 88 is formed between the intersection 86 and the peripheral wall of the opening 84 for eliminating the aforementioned capillary action.

In conclusion, the heat sink of the present invention can effectively prevent the solder from sinking into the chamber, thereby not only securing the solder in position from absorbed by the capillary action, but also further securing the capillary layer from vitiation caused by the melted solder to improve the prior art.

1. A structurally sealed heat sink comprising:
a main body having a chamber inside, a capillary layer disposed around a peripheral surface of said chamber, at least one opening formed for a predetermined depth, and a peripheral wall formed around said opening for a predetermined height;
at least one sealing member being the same with said opening in number and having an intersection intersected with said opening for the predetermined depth, a solder ditch being formed between said sealing member and said main body, an annular groove being formed between said peripheral wall and an outer periphery of said sealing member; and
at least one solder unit being the same with said opening in number and disposed in said solder ditch.

2. The heat sink as defined in claim 1, wherein said solder ditch is recessed around an end of said opening of said main body.

3. The heat sink as defined in claim 1, wherein said solder ditch is recessed around a periphery of said sealing member.

4. The heat sink as defined in claim 1, wherein said annular groove is recessed around a periphery of said sealing member.

5. The heat sink as defined in claim 1, wherein said annular groove is recessed on said main body.

6. The heat sink as defined in claim 1, wherein said main body is a metallic block; said sealing member is a heat pipe having a free end mounted to said opening of said main body.

7. The heat sink as defined in claim 1, wherein said main body is a metallic block; said sealing member is a stopping barrel member mounted to said opening of said main body.

8. The heat sink as defined in claim 1, wherein said main body is a heat pipe; said sealing member is a piston barrel mounted to said opening of said main body.

9. The heat sink as defined in claim 1, wherein said main body is a heat pipe; said sealing member is a sleeve fitted to said opening of said main body.
